(19) United States
(12) Patent Application Publication
(10) Pub. No.: US 2025/0057058 A1
(43) Pub. Date: Feb. 13, 2025

(54) RESISTIVE MEMORY ELEMENTS WITH A MULTIPLE-MATERIAL ELECTRODE

(71) Applicant: GlobalFoundries Singapore Pte. Ltd., Singapore (SG)

(72) Inventors: Curtis Chun-I Hsieh, Singapore (SG); Kai Kang, Singapore (SG)

(21) Appl. No.: 18/232,868

(22) Filed: Aug. 11, 2023

(51) Int. Cl. H10N 70/00; H10B 63/00

(52) U.S. Cl. CPC H10N 70/883; H10B 63/30; H10N 70/841

(57) ABSTRACT

Structures for a resistive memory element and methods of forming a structure for a resistive memory element. The structure comprises a resistive memory element including a first electrode, a second electrode, and a switching layer between the first electrode and the second electrode. The first electrode includes a first metal feature and a second metal feature inside the first metal feature. The first metal feature comprising a first metal, and the second metal feature comprises a second metal with a different composition than the first metal. The first metal feature adjoins a first portion of the switching layer, and the second metal feature adjoins a second portion of the switching layer.

### BACKGROUND

This disclosure relates to integrated circuits and semiconductor device fabrication and, more specifically, to structures for a resistive memory element and methods of forming a structure for a resistive memory element.

A resistive random-access memory device provides one category of embedded non-volatile memory technology. A bitcell of a resistive random-access memory device typically includes a resistive memory element and an access transistor that controls operations used to write, erase, and read the resistive memory element. Because resistive memory elements are non-volatile, bits of data are retained as stored content by the resistive memory elements when the resistive random-access memory device is unpowered. The non-volatility of a resistive random-access memory device contrasts with volatile memory technologies, such as a static random-access memory device in which the stored content is eventually lost when unpowered and a dynamic random-access memory device in which the stored content is lost unless periodically refreshed.

A resistive memory element includes a switching layer that is positioned in a layer stack between a bottom electrode and a top electrode. The resistive memory element can be written and erased by changing the resistance across the switching layer to provide different content-storage conditions, namely a high-resistance state and a low-resistance state, representing the stored bits of data. The switching layer can be written by applying a programming voltage across the bottom and top electrodes that is sufficient to create one or more conductive filaments bridging across the thickness of the switching layer, which sets the low-resistance state. The conductive filaments can be destroyed, also by the application of a programming voltage, to reset the resistive memory element to the high-resistance state. The content-storage condition can be read by measuring a voltage drop across the resistive memory element.

Improved structures for a resistive memory element and methods of forming a structure for a resistive memory element are needed.

### SUMMARY

According to an embodiment of the invention, a structure for a random-access resistive memory device is provided. The structure comprises a resistive memory element including a first electrode, a second electrode, and a switching layer between the first electrode and the second electrode. The first electrode includes a first metal feature and a second metal feature inside the first metal feature. The first metal feature comprises a first metal, and the second metal feature comprises a second metal with a different composition than the first metal. The first metal feature adjoins a first portion of the switching layer, and the second metal feature adjoins a second portion of the switching layer.

According to another embodiment of the invention, a method of forming a structure for a random-access resistive memory device is provided. The method comprises forming a first metal feature of a first electrode of a resistive memory element, forming a second metal feature of the first electrode inside the first metal feature, forming a switching layer of the resistive memory element, and forming a second electrode of the resistive memory element. The switching layer is disposed between the first electrode and the second electrode, the first metal feature adjoins a first portion of the switching layer, and the second metal feature adjoins a second portion of the switching layer. The first metal feature comprises a first metal, and the second metal feature comprises a second metal with a different composition than the first metal.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a bitcell structure at an initial fabrication stage of a processing method in accordance with embodiments of the invention.

FIG. 1A is a top view of the bitcell structure in which FIG. 1 is taken generally along line 1-1.

FIG. 2 is a cross-sectional view of the bitcell structure at a fabrication stage subsequent to FIG. 1.

FIG. 3 is a cross-sectional view of the bitcell structure at a fabrication stage subsequent to FIG. 2.

FIG. 4 is a cross-sectional view of the bitcell structure at a fabrication stage subsequent to FIG. 3.

FIG. 5 is a cross-sectional view of a bitcell structure in accordance with alternative embodiments of the invention.

### DETAILED DESCRIPTION

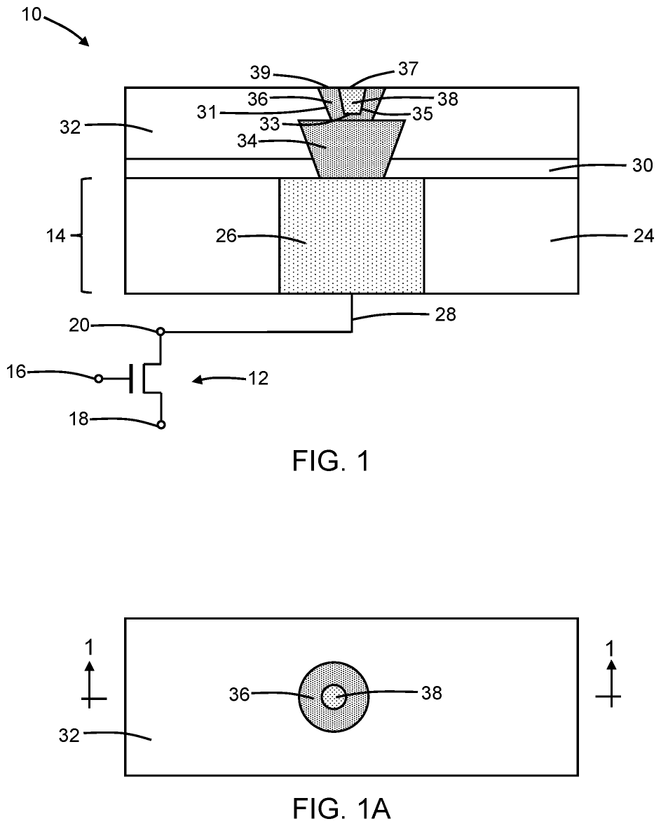

With reference to FIGS. 1, 1A and in accordance with embodiments of the invention, a bitcell 10 for a resistive random access memory device includes a transistor 12 and a metallization level 14 of an interconnect structure over the transistor 12. The transistor 12 may include a gate electrode 16, a source 18, and a drain 20, and the transistor 12 may be formed by front-end-of-line processing of a substrate, such as a silicon-on-insulator substrate or a bulk semiconductor substrate. The gate electrode 16 may be comprised of a gate conductor, such as doped polycrystalline silicon (i.e., polysilicon) or one or more work-function metals, and a gate dielectric comprised of an electrical insulator, such as silicon dioxide or a high-k dielectric material, may separate the gate electrode 16 from the substrate. The source 18 and drain 20 may be comprised of doped semiconductor material, such as doped silicon or doped silicon-germanium, that is formed in and/or on the substrate. The transistor 12 is configured to control access to a subsequently-formed non-volatile memory element.

The metallization level 14 may be fabricated by back-end-of-line processing as a wiring layer of the interconnect structure. The metallization level 14 may include an interlayer dielectric layer 24 and a metal feature 26 disposed in the interlayer dielectric layer 24. The interlayer dielectric layer 24 may be comprised of a dielectric material, such as silicon dioxide or a low-k dielectric material, that is an electrical insulator, and the metal feature 26 may be comprised of a metal, such as copper, that is a conductor. The interconnect structure may include additional metallization levels (not shown) between the transistor 12 and the metallization level 14. The drain 20 of the transistor 12 may be coupled to the metal feature 26 by an interconnection 28 formed in the additional metallization levels. The interconnection 28 to the metal feature 26 may include metal islands, vias, and/or contacts arranged in the interlayer dielectric layers of the additional metallization levels.

Dielectric layers 30, 32 may be formed over the metallization level 14. The dielectric layer 30 may be comprised of a dielectric material, such as silicon-carbon nitride or hydrogenated silicon-carbon nitride, that is an electrical insulator. The dielectric layer 32 may be comprised of a different dielectric material, such as silicon dioxide, that is an electrical insulator. Silicon dioxide comprising the dielectric layer 32 may be formed by plasma-enhanced chemical vapor deposition using ozone and tetraethylorthosilicate as reactants.

A metal feature 34 may be formed as a via in the dielectric layer 30. The metal feature 34 may include a lower portion that adjoins a top surface of the metal feature 26. A metal feature 36 may be formed as a via in the dielectric layer 32. The metal feature 36 has a lower portion that adjoins an upper portion of the metal feature 34. The metal feature 34 is disposed in a vertical direction between the metal feature 36 and the metal feature 26 in the metallization level 14. The metal features 34, 36 may be comprised of a metal, such as tantalum nitride, and the metal features 34, 36 may be formed by deposition and planarization in respective openings that are patterned by lithography and etching processes in the dielectric layers 30, 32.

A metal feature 38 may be formed inside, and embedded in, the metal feature 36. In an embodiment, the metal feature 38 may be formed by patterning an opening in the metal feature 36, depositing its constituent metal, and planarizing the deposited metal. In an embodiment, the metal feature 38 and its associated opening may penetrate from a top surface 39 of the metal feature 36 partially through the metal feature 36 such that a partial thickness of the metal feature 36 is disposed between the metal feature 38 and the metal feature 34. In an embodiment, the metal feature 38 may be centered inside the metal feature 36. The metal feature 38 includes a bottom surface 33, a top surface 37, and a side surface 35 that extends from the bottom surface 33 to the top surface 37. The bottom surface 33 and the side surface 35 of the metal feature 38 are surrounded by the metal feature 36 such that the metal feature 38 is embedded in the metal feature 36. The bottom surface 33 and the side surface 35 of the metal feature 38 may adjoin the metal feature 36 and, in an embodiment, bottom surface 33 and the side surface 35 of the metal feature 38 may directly contact the metal feature 36. The top surface 37 of the metal feature 38 is bounded by the top surface 39 of the metal feature 36 in that the top surface 37 of the metal feature 38 has a perimeter that is surrounded by the top surface 39 of the metal feature 36.

The metal feature 38 may be comprised of a different metal than the metal feature 36. In an embodiment, the metal feature 38 may be comprised of a metal that is capable of gettering or scavenging a reactive species, such as oxygen. In an embodiment, the metal feature 38 may be comprised of a metal having a stronger affinity to bond with oxygen than the metal of the metal feature 36. In an embodiment, the metal feature 38 may be comprised of titanium. In an alternative embodiment, the metal feature 38 may be comprised of hafnium. In an alternative embodiment, the metal feature 38 may be comprised of tantalum. In an alternative embodiment, the metal feature 38 may be comprised of zirconium. In an embodiment, the metal feature 38 may be comprised of a metal that lacks nitrogen in its composition.

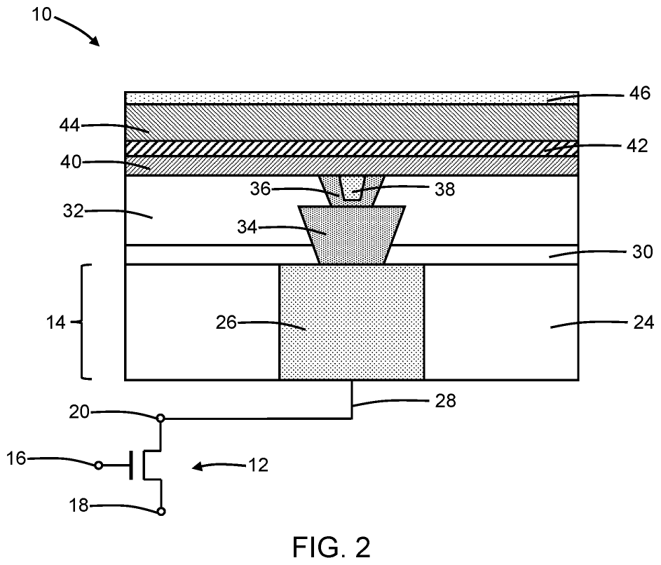

With reference to FIG. 2 in which like reference numerals refer to like features in FIGS. 1, 1A and at a subsequent fabrication stage, multiple layers 40, 42, 44, 46 may be formed in a layer stack on, and over, the dielectric layers 30, 32. The layers 40, 42, 44, 46 overlap with the underlying metal features 34, 36, 38. The layer 40 may be comprised of a metal oxide, such as hafnium oxide, that is capable of functioning as a switching layer in the completed device. The layer 42 may be comprised of a noble metal, such as platinum. The layer 44 may be comprised of a metal, such as tantalum nitride. The layer 46 may be comprised of a dielectric material, such as silicon nitride.

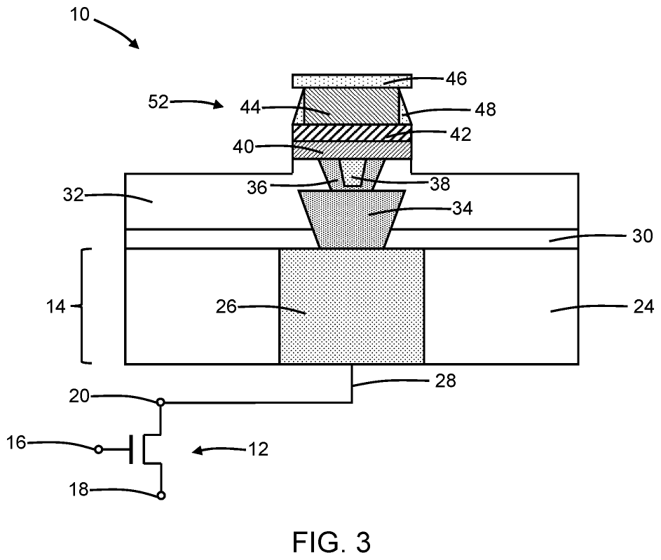

With reference to FIG. 3 in which like reference numerals refer to like features in FIG. 2 and at a subsequent fabrication stage, the layers 40, 42, 44, 46 of the layer stack are patterned by lithography and etching processes to form a non-volatile memory element 52. The layer 46 may be initially patterned to define a hardmask that is subsequently used to pattern the underlying layers 40, 42, 44. The etching process used to pattern the layers 40, 42, 44 may be a reactive ion etching process that relies on a gas mixture containing argon and oxygen. The dielectric layer 32 may function as an etch stop during the reactive ion etching process. Spacers 48 may be formed at the periphery of the etched layer 44 by the oxidation of peripheral portions of the metal of the layer 44 during the reactive ion etching process. The spacers 48 may be comprised of a metal oxynitride, such as tantalum oxynitride. The etched layer 46 is disposed on an inner portion of the etched layer 44, and the spacers 48 are disposed on outer portions of the etched layer 44.

The etched layer 40 overlaps with the metal feature 36, and the etched layer 40 also overlaps with the metal feature 38 embedded in the metal feature 36. A portion of the etched layer 40 adjoins the top surface 37 of the metal feature 38. A portion of the etched layer 40 adjoins the top surface 39 of the metal feature 36. In an embodiment, the metal feature 38 may be fully overlapped by the etched layer 40. In an embodiment, the metal feature 36 and the metal feature 38 may be fully overlapped by the etched layer 40.

The metal feature 36 and the metal feature 38 may collectively define a bottom electrode of the non-volatile memory element 52. The etched layer 42 and the etched layer 44 may collectively define a top electrode of the non-volatile memory element 52. The etched layer 42 of the top electrode may adjoin the switching layer defined by the etched layer 40. The etched layer 40 may define a switching layer that is disposed in a vertical direction between the top electrode and the bottom electrode. The metal feature 36 and the metal feature 38 of the bottom electrode may both adjoin the switching layer defined by the etched layer 44. In an embodiment, the metal feature 36 may have a width that increases with decreasing distance from the switching layer. In an embodiment, the metal feature 38 may have a width that increases with decreasing distance from the switching layer.

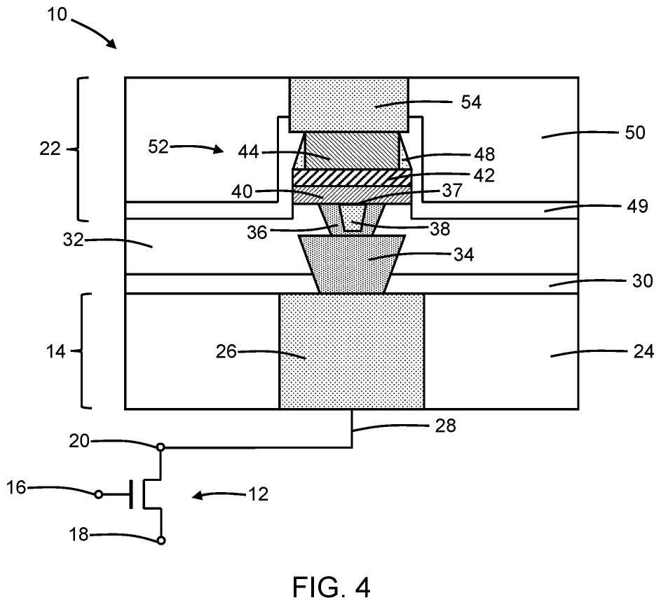

With reference to FIG. 4 in which like reference numerals refer to like features in FIG. 3 and at a subsequent fabrication stage, dielectric layers 49, 50 of a metallization level 22 may be formed over the non-volatile memory element 52, and a metal feature 54 may be formed in the dielectric layers 49, 50. The dielectric layer 49 may be comprised of a dielectric material, such as silicon nitride, that is an electrical insulator, and the dielectric layer 49 may define a conformal capping layer that extends across and coats the non-volatile memory element 52. The dielectric layer 50 may be comprised of a dielectric material, such as silicon dioxide or a low-k dielectric material, that is an electrical insulator. The metal feature 54 may be comprised of a metal, such as copper, that is a conductor. The metal feature 54 may be physically and electrically connected to the etched layer 44 of the top electrode of the non-volatile memory element 52. In an embodiment, the metal feature 54 may adjoin the etched layer 44 of the top electrode.

In use, an electric field applied between the top electrode and the bottom electrode may provide either a low-resistance state or a high-resistance state by resistive switching in the switching layer. The resistive switching may set the low-resistance state through the redistribution of charged oxygen vacancies that forms conductive filaments between the top and bottom electrodes. The resistive switching may set the high-resistance state by disrupting the conductive filaments between the top and bottom electrodes.

The metal feature 38 is comprised of a material, as previously described, that is capable of gettering or scavenging oxygen. The metal feature 38 may modulate the oxygen profile of the switching layer defined by etched layer 40 to provide an oxygen enrichment near the center of etched layer 40 and, thereby, influence the switching area of the etched layer 40 during resistive switching to be concentrated at the top surface 37 of the metal feature 38. As a result, the presence of the metal feature 38 in the bottom electrode may function to reduce the area of the switching region to dimensions that are less than lithography process limits. The presence of the metal feature 38 in the bottom electrode also shifts the switching region away from the sidewalls of the layer stack and, therefore, away from any etching damage at the sidewalls.

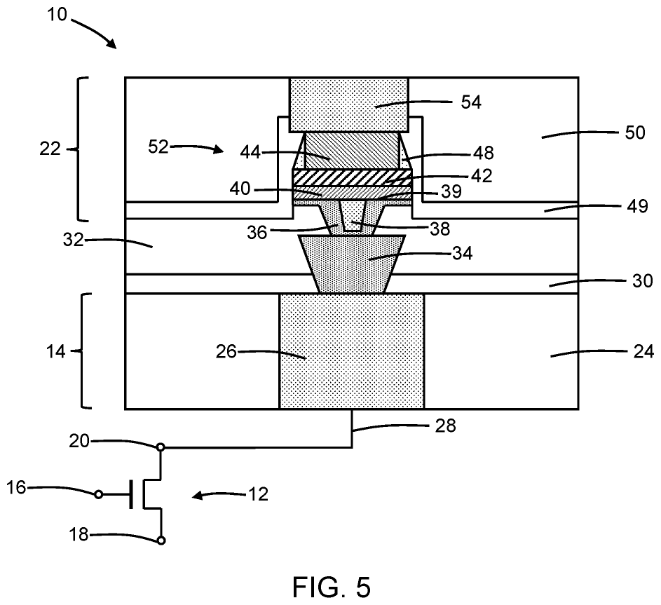

With reference to FIG. 5 and in accordance with alternative embodiments, the metal feature 36 may include a planar portion at its top surface 39 that is coterminous with the etched layer 40 at the sidewalls of the layer stack of the non-volatile memory element 52. The planar portion of the metal feature 36 may adjoin the lower portion of the metal feature 36. The metal feature 38 projects into, and through, the planar section of the metal feature 36 to adjoin the switching layer defined by the etched layer 40.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate a range of +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a random-access resistive memory device, the structure comprising:
a resistive memory element including a first electrode, a second electrode, and a switching layer between the first electrode and the second electrode, the first electrode including a first metal feature and a second metal feature inside the first metal feature, the first metal feature comprising a first metal, the second metal feature comprising a second metal with a different composition than the first metal, the first metal feature adjoining a first portion of the switching layer, and the second metal feature adjoining a second portion of the switching layer.

2. The structure of claim 1 wherein the first metal comprises tantalum nitride, and the second metal comprises titanium.

3. The structure of claim 1 wherein the first metal comprises tantalum nitride, and the second metal feature comprises zirconium.

4. The structure of claim 1 wherein the first metal comprises tantalum nitride, and the second metal comprises hafnium.

5. The structure of claim 1 wherein the first metal comprises tantalum nitride, and the second metal comprises tantalum and lacks nitrogen.

6. The structure of claim 1 wherein the second metal has a stronger affinity to bond with oxygen than the first metal.

7. The structure of claim 1 wherein the second metal feature is embedded in the first metal feature.

8. The structure of claim 7 wherein the second metal feature is centered in the first metal feature.

9. The structure of claim 7 wherein the second metal feature extends partially through the first metal feature.

10. The structure of claim 1 wherein the first metal feature includes a first portion having a first width that increases with decreasing distance from the switching layer, and the second metal feature has a second width that is less than the first width.

11. The structure of claim 10 wherein the first metal feature includes a second portion that is coterminous with the switching layer.

12. The structure of claim 11 wherein the second portion of the first metal feature has a top surface, and the second metal feature has a top surface that is coplanar with the top surface of the first metal feature.

13. The structure of claim 10 wherein the first portion of the first metal feature is a first via, and further comprising:
a second via,
wherein the first via is disposed over the second via, and the second via comprises the first metal.

14. The structure of claim 13 wherein a portion of the first via is disposed between the second metal feature and the second via.

15. The structure of claim 1 further comprising:
a field-effect transistor including a drain coupled to the first electrode.

16. The structure of claim 1 wherein the first metal feature has a top surface, and the second metal feature has a top surface that is coplanar with the top surface of the first metal feature.

17. The structure of claim 16 wherein the top surface of the first metal feature adjoins the first portion of the switching layer, and the top surface of the second metal feature adjoins the second portion of the switching layer.

18. The structure of claim 17 wherein the top surface of the first metal feature borders the top surface of the second metal feature.

19. The structure of claim 1 wherein the second metal feature has a top surface, a bottom surface, and a side surface, the top surface adjoins the switching layer, the side surface adjoins the first metal feature, and the bottom surface adjoins the first metal feature.

20. A method of forming a structure for a random-access resistive memory device, the method comprising:
forming a first metal feature of a first electrode of a resistive memory element;
forming a second metal feature of the first electrode inside the first metal feature;
forming a switching layer of the resistive memory element; and
forming a second electrode of the resistive memory element,
wherein the switching layer is disposed between the first electrode and the second electrode, the first metal feature comprises a first metal, the second metal feature comprises a second metal with a different composition than the first metal, the first metal feature adjoins a first portion of the switching layer, and the second metal feature adjoins a second portion of the switching layer.
